(19) United States
(12) Patent Application Publication
(10) Pub. No.: US 2025/0221235 A1
(43) Pub. Date: Jul. 3, 2025

(54) Light-Emitting Diode Display Device

(71) Applicant: LG Display Co., Ltd., Seoul (KR)

(72) Inventor: Chan-Il Park, Paju-si (KR)

(21) Appl. No.: 18/961,915

(22) Filed: Nov. 27, 2024

(30) Foreign Application Priority Data
Dec. 29, 2023 (KR) 10-2023-0195964

(51) Int. Cl. H10K 59/70; H10K 59/35; H10K 59/80

(52) U.S. Cl. CPC H10K 59/70; H10K 59/352; H10K 59/873

(57) ABSTRACT

A light-emitting diode display device includes a substrate; a plurality of pixels arranged in a first direction and a second direction on the substrate, each of the plurality of pixels including a first sub-pixel and a second sub-pixel; a first light-emitting element in the first sub-pixel; a second light-emitting element in the second sub-pixel; and a dam structure between the first sub-pixel and the second sub-pixel of each of the plurality of pixels, wherein the first sub-pixels of two pixels adjacent to each other in the first direction are disposed between the second sub-pixels of the two pixels and disposed between the dam structures provided in the two pixels.

### CROSS-REFERENCE TO RELATED APPLICATION

The present application claims priority to Republic of Korea Patent Application No. 10-2023-0195964 filed on Dec. 29, 2023, which is hereby incorporated by reference in its entirety.

### FIELD OF TECHNOLOGY

The present disclosure relates to a display device, and more particularly, to a light-emitting diode display device.

### BACKGROUND

As the information society progresses, a demand for different types of display devices increases, and flat panel display devices (FPD) such as liquid crystal display devices (LCD) and light-emitting diode (LED) display devices have been developed and applied to various fields.

Among the flat panel display devices, light-emitting diode display devices emit light due to the radiative recombination of an exciton. The exciton is formed from an electron and a hole by injecting charges into a light-emitting layer between a cathode for injecting electrons and an anode for injecting holes in a light-emitting diode.

The light-emitting diode display device has wide viewing angles as compared with a liquid crystal display device because it is self-luminous and also has advantages of a thin thickness, light weight and low power consumption since a backlight unit is not necessary.

The light-emitting diode display device includes a plurality of pixels, each of which comprises red, green, and blue sub-pixels and allows light-emitting elements of the red, green, and blue sub-pixels to selectively emit light, thereby displaying various color images.

In this case, the light-emitting diode display device includes inorganic light-emitting diodes or organic light-emitting diodes as light-emitting elements. That is, the light-emitting diode display device includes red, green, and blue organic light-emitting diodes or red, green, and blue inorganic light-emitting diodes.

By the way, since the blue organic light-emitting diode has relatively low quantum efficiency, the light efficiency is reduced. Accordingly, the luminance of the blue organic light-emitting diode is low and the lifetime of the blue organic light-emitting diode is short, which decreases the lifetime of the display device.

Meanwhile, the luminance of the red inorganic light-emitting diode is reduced due to relatively low quantum efficiency and heat generation. Accordingly, there are problems that the lifetime of the red inorganic light-emitting diode is short and reliability is low.

### SUMMARY

Accordingly, the present disclosure is to provide a light-emitting diode display device that substantially obviates one or more of the limitations and disadvantages described above and associated with the background art.

More specifically, an object of the present disclosure is to provide a light-emitting diode display device with improved light efficiency and brightness.

Additional features and embodiments will be set forth in the description that follows, and in part will be apparent from the description, or can be learned by practice of the present disclosure provided herein. Other features and embodiments of the inventive concepts can be realized and attained by the structure particularly pointed out in the written description, or derivable therefrom, and the claims hereof as well as the appended drawings.

To achieve these and other aspects of the present disclosure, as embodied and broadly described herein, a light-emitting diode display device includes a substrate; a plurality of pixels arranged in a first direction and a second direction on the substrate, each of the plurality of pixels including a first sub-pixel and a second sub-pixel; a first light-emitting element in the first sub-pixel; a second light-emitting element in the second sub-pixel; and a dam structure between the first sub-pixel and the second sub-pixel of each of the plurality of pixels, wherein the first sub-pixels of two pixels adjacent to each other in the first direction are disposed between the second sub-pixels of the two pixels and disposed between the dam structures provided in the two pixels.

It is to be understood that both the foregoing general description and the following detailed description are examples and are intended to provide further explanation of the inventive concepts as claimed.

### BRIEF DESCRIPTION OF THE DRAWINGS

The accompanying drawings, which are included to provide a further understanding of the present disclosure and which are incorporated in and constitute a part of this application, illustrate aspects of the disclosure and together with the description serve to explain various principles of the present disclosure.

In the drawings:

FIG. 1 is a schematic plan view of a light-emitting diode display device according to an embodiment of the present disclosure;

FIG. 2 is an equivalent circuit diagram for a sub-pixel of a light-emitting diode display device according to an embodiment of the present disclosure;

FIG. 3 is a schematic cross-sectional view of a light-emitting diode display device according to an embodiment of the present disclosure;

FIG. 4 is a schematic plan view of a light-emitting diode display device according to a first embodiment of the present disclosure;

FIG. 5 is a schematic cross-sectional view of a light-emitting diode display device according to the first embodiment of the present disclosure;

FIG. 6 is a schematic cross-sectional view of a light-emitting diode display device of another example according to the first embodiment of the present disclosure;

FIG. 7 is a schematic plan view of a light-emitting diode display device according to a second embodiment of the present disclosure; and

FIG. 8 is a schematic plan view of a light-emitting diode display device according to a third embodiment of the present disclosure.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein or may be briefly discussed.

When terms such as “including,” “having,” “comprising” and the like mentioned in this disclosure are used, other parts can be added unless the term “only” is used herein. Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

Although the terms first, second, and the like are used to describe various components, these components are not substantially limited by these terms. These terms are used only to distinguish one component from another component and may not define any order or sequence. Therefore, a first component described below can substantially be a second component within the technical spirit of the present disclosure.

Features of various embodiments of the present disclosure can be partially or entirely united or combined with each other, technically various interlocking and driving are possible, and each of the embodiments can be independently implemented with respect to each other or implemented together in a related relationship.

Hereinafter, exemplary embodiments of the present disclosure will be described in detail with reference to accompanying drawings.

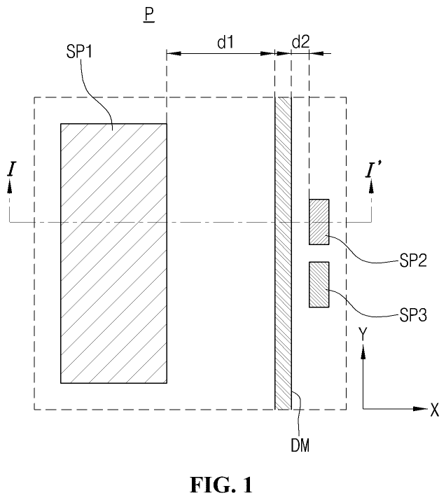

FIG. 1 is a schematic plan view of a light-emitting diode display device according to an embodiment of the present disclosure and shows one pixel.

In FIG. 1, one pixel P of a light-emitting diode display device according to an embodiment of the present disclosure may include a first sub-pixel SP1, a second sub-pixel SP2, and a third sub-pixel SP3. For example, the first sub-pixel SP1 may be a red sub-pixel, the second sub-pixel SP2 may be one of green and blue sub-pixels, and the third sub-pixel SP3 may be the other of the green and blue sub-pixels.

The first sub-pixel SP1 may be spaced apart from the second sub-pixel SP2 and the third sub-pixel SP3 in a first direction X. In addition, the second sub-pixel SP2 and the third sub-pixel SP3 may be spaced apart from each other in a second direction Y However, embodiments of the present disclosure are not limited thereto. In other embodiments, the first sub-pixel SP1 may be spaced apart from the second sub-pixel SP2 and the third sub-pixel SP3 in the second direction Y, and the second sub-pixel SP2 and the third sub-pixel SP3 may be spaced apart from each other in the first direction X.

A distance between the first sub-pixel SP1 and the second sub-pixel SP2 or the third sub-pixel SP3 may be greater than a distance between the second sub-pixel SP2 and the third sub-pixel SP3. In addition, the area of the first sub-pixel SP1 may be greater than the area of the second and third sub-pixels SP2 and SP3.

A first light-emitting element may be provided in the first sub-pixel SP1, a second light-emitting element may be provided in the second sub-pixel SP2, and a third light-emitting element may be provided in the third sub-pixel SP3. For example, the first light-emitting element may emit red light, the second light-emitting element may emit one of green light or blue light, and the third light-emitting element may emit the other of the green light or the blue light. Here, the first light-emitting element may be an organic light-emitting diode, and the second and third light-emitting elements may be inorganic light-emitting diodes.

A dam structure DM may be provided between the first sub-pixel SP1 and the second and third sub-pixels SP2 and SP3. A first distance d1 between the dam structure DM and the first sub-pixel SP1 may be greater than a second distance d2 between the dam structure DM and the second and third sub-pixels SP2 and SP3. This will be described in detail later.

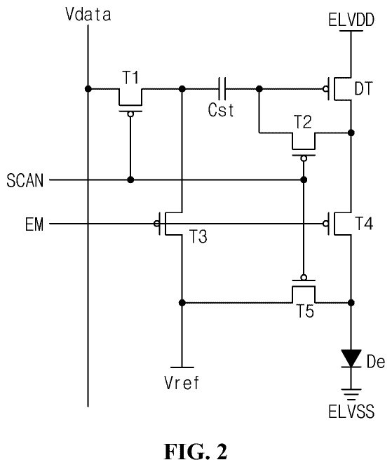

FIG. 2 is an equivalent circuit diagram for a sub-pixel of a light-emitting diode display device according to an embodiment of the present disclosure.

In FIG. 2, one sub-pixel of the light-emitting diode display device according to the embodiment of the present disclosure, that is, each of the first, second, and third sub-pixels SP1, SP2, and SP3 of FIG. 1 may include a driving transistor DT, first, second, third, fourth, and fifth transistors T1, T2, T3, T4, and T5, a storage capacitor Cst, and a light-emitting element De.

For example, the driving transistor DT and the first, second, third, fourth, and fifth transistors T1, T2, T3, T4, and T5 may be P-type transistors. However, embodiments of the present disclosure are not limited thereto. In other embodiments, the driving transistor DT and the first, second, third, fourth, and fifth transistors T1, T2, T3, T4, and T5 may be N-type transistors.

The driving transistor DT may be switched according to a voltage of a first capacitor electrode of the storage capacitor Cst and may be connected to a high potential voltage ELVDD. Specifically, a gate of the driving transistor DT may be connected to the first capacitor electrode of the storage capacitor Cst and a source of the second transistor T2. A source of the driving transistor DT may be connected to the high potential voltage ELVDD. A drain of the driving transistor DT may be connected to a drain of the second transistor T2 and a source of the fourth transistor T4.

The first transistor T1 may be switched according to a scan signal SCAN and may be connected to a data signal Vdata. Specifically, a gate of the first transistor T1 may be connected to the scan signal SCAN. A source of the first transistor T1 may be connected to the data signal Vdata. A drain of the first transistor T1 may be connected to a second capacitor electrode of the storage capacitor Cst and a source of the third transistor T3.

The second transistor T2 may be switched according to the scan signal SCAN and may be connected to the driving transistor DT. Specifically, a gate of the second transistor T2 may be connected to the scan signal SCAN. The source of the second transistor T2 may be connected to the first capacitor electrode of the storage capacitor Cst and the gate of the driving transistor DT. The drain of the second transistor T2 may be connected to the drain of the driving transistor DT and the source of the fourth transistor T4.

The third transistor T3 may be switched according to an emission signal EM and may be connected to a reference voltage Vref Specifically, a gate of the third transistor T3 may be connected to the emission signal EM. The source of the third transistor T3 may be connected to the second capacitor electrode of the storage capacitor Cst and the drain of the first transistor T1. A drain of the third transistor T3 may be connected to the reference voltage Vref and a source of the fifth transistor T5.

The fifth transistor T5 may be switched according to the scan signal SCAN and may be connected to the reference voltage Vref and the fourth transistor T4. Specifically, a gate of the fifth transistor T5 may be connected to the scan signal SCAN. The source of the fifth transistor T5 may be connected to the reference voltage Vref and the drain of the third transistor T3. The drain of the fifth transistor T5 may be connected to the drain of the fourth transistor T4 and the first electrode of the light-emitting element De.

The storage capacitor Cst may store the data signal Vdata and a threshold voltage Vth of the driving transistor DT. The first capacitor electrode of the storage capacitor Cst may be connected to the gate of the driving transistor DT and the source of the second transistor T2. The second capacitor electrode of the storage capacitor Cst may be connected to the drain of the first transistor T1 and the source of the third transistor T3.

The light-emitting element De may be connected between the fourth and fifth transistors T4 and T5 and a low potential voltage ELVSS and may emit light with luminance proportional to a current of the driving transistor DT. The first electrode of the light-emitting element De, which is an anode, may be connected to the drain of the fourth transistor T4 and the drain of the fifth transistor T5. The second electrode of the light-emitting element De, which is a cathode, may be connected to the low potential voltage ELVSS.

In the embodiment of the present disclosure of FIG. 2, as an example, each sub-pixel has a 6T1C structure including six transistors and one capacitor, but in other embodiments, each sub-pixel may have one of 2T1C, 3T1C, 4T1C, 5T1C, 3T2C, 4T2C, 5T2C, 6T2C, 7T1C, 7T2C, 8T1C, and 8T2C structures.

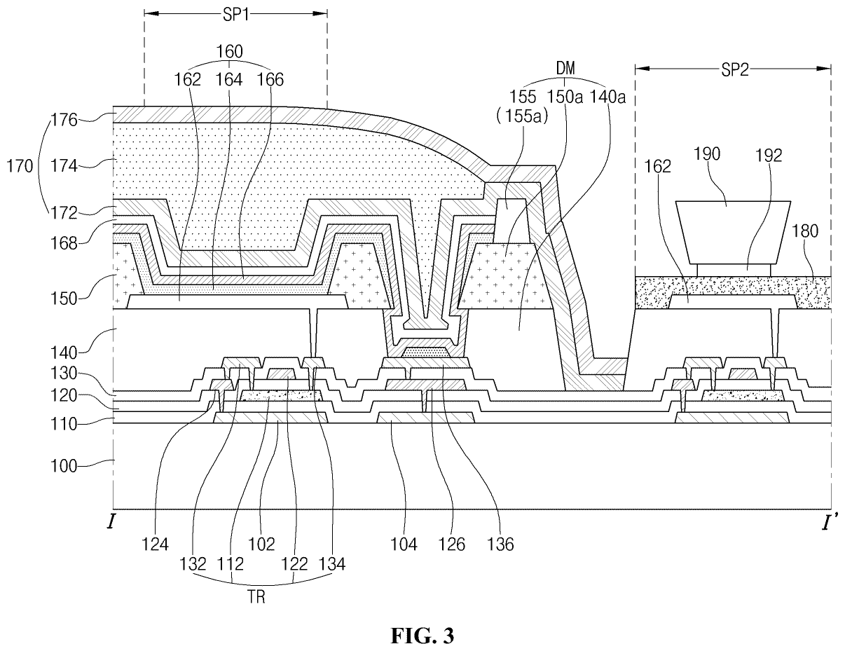

A cross-sectional structure of a light-emitting diode display device according to an embodiment of the present disclosure will be described in detail with reference to FIG. 3.

FIG. 3 is a schematic cross-sectional view of a light-emitting diode display device according to an embodiment of the present disclosure. FIG. 3 shows a cross-section corresponding to line I-I′ of FIG. 1 and will be described with reference to FIGS. 1 to 2 together.

In FIG. 3, the light-emitting diode display device according to the embodiment of the present disclosure may include a substrate 100 and a plurality of sub-pixels SP1 and SP2, a thin film transistor TR and a light-emitting element 160 or 190 may be provided in each of the plurality of sub-pixels SP1 and SP2, and a dam structure DM may be provided between the light-emitting elements 160 and 190.

Specifically, first and second sub-pixels SP1 and SP2 are provided on the substrate 100. In addition, although not shown in the figure, a third sub-pixel SP3 of FIG. 1 may be further provided on the substrate 100, and the third sub-pixel SP3 may have substantially the same configuration as the second sub-pixel SP2.

The substrate 100 may be a glass substrate or a plastic substrate. For example, polyimide (PI) may be used for the plastic substrate, but embodiments of the present disclosure are not limited thereto.

A light-shielding layer 102 and a power line 104 may be provided on the substrate 100. The light-shielding layer 102 may be disposed in each of the first and second sub-pixels SP1 and SP2. The power line 104 may be disposed between the first sub-pixel SP1 and the second sub-pixel SP2. For example, the power line 104 may be a lower potential power line supplying the low potential voltage ELVSS.

The light-shielding layer 102 and the power line 104 may be formed of a conductive material such as metal. For example, the light-shielding layer 102 and the power line 104 may be formed of at least one of aluminum (Al), copper (Cu), molybdenum (Mo), titanium (Ti), chromium (Cr), nickel (Ni), tungsten (W), or an alloy thereof. The light-shielding layer 102 and the power line 104 may have a single-layered structure or a multiple-layered structure.

A buffer layer 110 may be provided on the light-shielding layer 102 and the power line 104 as a first insulation layer. The buffer layer 110 may be disposed over substantially an entire surface of the substrate 100. The buffer layer 110 may be formed as a single layer or multiple layers of an inorganic insulating material. The inorganic insulating material of the buffer layer 110 may include silicon nitride (SiNx), silicon oxide (SiOx), or silicon oxynitride (SiON).

A semiconductor layer 112 may be provided on the buffer layer 110. The semiconductor layer 112 may be disposed in each of the first and second sub-pixels SP1 and SP2.

The semiconductor layer 112 may overlap the light-shielding layer 102, and the light-shielding layer 102 may block light incident on the semiconductor layer 112 and prevent or at least reduce the semiconductor layer 112 from deteriorating due to the light.

The semiconductor layer 112 may include a channel region at its central part and source and drain regions at both sides of the channel region.

The semiconductor layer 112 may be formed of an oxide semiconductor material. Alternatively, the semiconductor layer 112 may be formed of polycrystalline silicon, and in this case, both ends of the semiconductor layer 112 may be doped with impurities.

A gate insulation layer 120 may be provided on the semiconductor layer 112 as a second insulation layer. The gate insulation layer 120 may be disposed over substantially the entire surface of the substrate 100. The gate insulation layer 120 may be formed as a single layer or multiple layers of an inorganic insulating material. The inorganic insulating material of the gate insulation layer 120 may include silicon nitride (SiNx), silicon oxide (SiOx), or silicon oxynitride (SiON).

A gate electrode 122, a connection electrode 124, and a first auxiliary electrode 126 may be provided on the gate insulation layer 120. The gate electrode 122 and the connection electrode 124 may be disposed in each of the first and second sub-pixels SP1 and SP2. The first auxiliary electrode 126 may be disposed between the first sub-pixel SP1 and the second sub-pixel SP2.

The gate electrode 122 may overlap the semiconductor layer 112 and may be disposed to correspond to the central part of the semiconductor layer 112. Accordingly, the gate electrode 122 may also overlap the light-shielding layer 102.

The connection electrode 124 may overlap the light-shielding layer 102 and may be in contact with the light-shielding layer 102 through a contact hole provided in the buffer layer 110 and the gate insulation layer 120. The connection electrode 124 may be spaced apart from the semiconductor layer 112.

The first auxiliary electrode 126 may overlap the power line 104 and may be in contact with the power line 104 through a contact hole provided in the buffer layer 110 and the gate insulation layer 120.

The gate electrode 122, the connection electrode 124, and the first auxiliary electrode 126 may be formed of a conductive material such as metal. For example, the gate electrode 122 and the connection electrode 124 may be formed of at least one of aluminum (Al), copper (Cu), molybdenum (Mo), titanium (Ti), chromium (Cr), nickel (Ni), tungsten (W), or an alloy thereof. The gate electrode 122, the connection electrode 124, and the first auxiliary electrode 126 may have a single-layered structure or a multiple-layered structure.

An interlayer insulation layer 130 may be provided on the gate electrode 122, the connection electrode 124, and the first auxiliary electrode 126 as a third insulation layer. The interlayer insulation layer 130 may be disposed over substantially the entire surface of the substrate 100. The interlayer insulation layer 130 may be formed as a single layer or multiple layers of an inorganic insulating material. The inorganic insulating material of the interlayer insulation layer 130 may include silicon nitride (SiNx), silicon oxide (SiOx), or silicon oxynitride (SiON).

A source electrode 132, a drain electrode 134, and a second auxiliary electrode 136 may be provided on the interlayer insulation layer 130. The source electrode 132 and the drain electrode 134 may be disposed in each of the first and second sub-pixels SP1 and SP2. The second auxiliary electrode 136 may be disposed between the first sub-pixel SP1 and the second sub-pixel SP2.

The source electrode 132 and the drain electrode 134 may be spaced apart from each other with the gate electrode 122 positioned therebetween and may be in contact with both ends of the semiconductor layer 112 through contact holes provided in the gate insulation layer 120 and the interlayer insulation layer 130. In addition, the source electrode 132 may overlap the connection electrode 124 and may be in contact with the connection electrode 124 through a contact hole provided in the interlayer insulation layer 130. Accordingly, the source electrode 132 may be electrically connected to the light-shielding layer 102.

The semiconductor layer 112, the gate electrode 122, the source electrode 132, and the drain electrode 134 may constitute the thin film transistor TR.

The second auxiliary electrode 136 may overlap the first auxiliary electrode 126 and may be in contact with the first auxiliary electrode 126 through a contact hole provided in the interlayer insulation layer 130. Accordingly, the second auxiliary electrode 136 may be electrically connected to the power line 104. In other embodiments, the first auxiliary electrode 126 may be omitted, and the second auxiliary electrode 136 may be directly connected to the power line 104.

The source electrode 132, the drain electrode 134, and the second auxiliary electrode 136 may be formed of a conductive material such as metal. For example, the source electrode 132, the drain electrode 134, and the second auxiliary electrode 136 may be formed of at least one of aluminum (Al), copper (Cu), molybdenum (Mo), titanium (Ti), chromium (Cr), nickel (Ni), tungsten (W), or an alloy thereof. The source electrode 132, the drain electrode 134, and the second auxiliary electrode 136 may have a single-layered structure or a multiple-layered structure.

A planarization layer 140 may be provided on the source electrode 132, the drain electrode 134, and the second auxiliary electrode 136 as a fourth insulation layer. The planarization layer 140 may be disposed over substantially the entire surface of the substrate 100. The planarization layer 140 may be removed over the second auxiliary electrode 136 to thereby expose the second auxiliary electrode 136.

In addition, the planarization layer 140 may be removed between the first sub-pixel SP1 and the second sub-pixel SP2 to thereby expose a top surface of the interlayer insulation layer 130 adjacent to the second sub-pixel SP2.

The planarization layer 140 may eliminate a step difference due to the layers thereunder and may have a substantially flat top surface. The planarization layer 140 may be formed of an organic insulating material such as photosensitive acrylic polymer (photo acryl) or benzocyclobutene (BCB).

Meanwhile, a passivation layer may be further provided under the planarization layer 140, specifically, between the planarization layer 140 and the source electrode 132, the drain electrode 134, and the second auxiliary electrode 136. The passivation layer may be formed as a single layer or multiple layers of an inorganic insulating material. The inorganic insulating material of the passivation layer may include silicon nitride (SiNx), silicon oxide (SiOx), or silicon oxynitride (SiON).

A first electrode 162 may be provided on the planarization layer 140. The first electrode 162 may be disposed in each of the first and second sub-pixels SP1 and SP2 and may be in contact with the drain electrode 134 through a contact hole provided in the planarization layer 140.

The first electrode 162 may be formed of a conductive material having relatively high work function. For example, the first electrode 162 may include a transparent conductive material such as indium tin oxide (ITO) or indium zinc oxide (IZO) or may include titanium (Ti).

In addition, the first electrode 162 may have a single-layered structure or a multiple-layered structure including a material with relatively high reflectance. For example, the first electrode 162 may be formed as a structure having relatively high reflectance such as a triple-layered structure of titanium, aluminum, and titanium (Ti/Al/Ti), a triple-layered structure of indium tin oxide, aluminum, and indium tin oxide (ITO/Al/ITO), a triple-layered structure of indium tin oxide, silver, and indium tin oxide (ITO/Ag/ITO), or a triple-layered structure of indium tin oxide, silver alloy, and indium tin oxide (ITO/Ag alloy/ITO). Here, the silver alloy can be an alloy of silver-palladium-copper (APC).

A bank layer 150 may be provided on the first electrode 162 in the first sub-pixel SP1. The bank layer 150 may overlap edges of the first electrode 162 and cover the edges of the first electrode 162. The bank layer 150 may expose a central portion of the first electrode 162.

In addition, the bank layer 150 may be provided on the planarization layer 140 between the first sub-pixel SP1 and the second sub-pixel SP2 and may not be provided in the second sub-pixel SP2.

The bank layer 150 may be formed as a single layer or multiple layers of an organic insulating material. For example, the bank layer 150 may be formed of polyimide, photosensitive acrylic polymer (photo acryl), or benzocyclobutene (BCB).

A light-emitting layer 164 may be provided on the first electrode 162 and the bank layer 150 in the first sub-pixel SP1. The light-emitting layer 164 may be in contact with the first electrode 162 exposed by the bank layer 150 and top and side surfaces of the bank layer 150.

For example, the light-emitting layer 164 may emit red light and may include at least one hole auxiliary layer, at least one light-emitting material layer, and at least one electron auxiliary layer. The hole auxiliary layer may include at least one of a hole injection layer (HIL) and a hole transport layer (HTL). The electron auxiliary layer may include at least one of an electron injection layer (EIL) and an electron transport layer (ETL).

The light-emitting layer 164 may be formed through a thermal evaporation method using a fine metal mask. In this case, a spacer 155 may be provided on the bank layer 150 in order to prevent the light-emitting layer 164 from being in contact with the fine metal mask and being damaged.

The spacer 155 may be disposed on a part of the bank layer 150. The spacer 155 may be formed of the same material as the bank layer 150. The spacer 155 may be provided between the first sub-pixel SP1 and the second sub-pixel SP2 and may be disposed adjacent to the second sub-pixel SP2.

Accordingly, the light-emitting layer 164 may be partially provided between the first sub-pixel SP1 and the second sub-pixel SP2 and may not be provided in the second sub-pixel SP2. The light-emitting layer 164 may be in contact with the side surface of the spacer 155 and may be spaced apart from the top surface of the spacer 155 without contacting the top surface of the spacer 155.

A second electrode 166 may be provided on the light-emitting layer 164 in the first sub-pixel SP1. The second electrode 166 may be formed of a conductive material having relatively low work function.

For example, the second electrode 166 may be formed of aluminum (Al), magnesium (Mg), silver (Ag), or an alloy thereof. In this case, the second electrode 166 may have a relatively thin thickness such that light from the light-emitting layer 164 can be transmitted therethrough. For example, the second electrode 166 may have a thickness of 5 nm to 10 nm, but embodiments of the present disclosure are not limited thereto.

Alternatively, in other embodiments, the second electrode 166 may be formed of a transparent conductive material such as indium gallium oxide (IGO) or IZO.

The second electrode 166 may be in contact with the side surface of the spacer 155 and may be spaced apart from the top surface of the spacer 155 without contacting the top surface of the spacer 155.

The first electrode 162, the light-emitting layer 164, and the second electrode 166 of the first sub-pixel SP1 may constitute the first light-emitting element 160. The first light-emitting element 160 may be an organic light-emitting diode in which at least one layer of the light-emitting layer 164 is formed of an organic material. Here, the first electrode 162 may serve as an anode, and the second electrode 166 may serve as a cathode. However, embodiments of the present disclosure are not limited thereto.

Meanwhile, since the light-emitting layer 164 has insulating properties and acts as a resistor, an undercut structure may be provided between the second auxiliary electrode 136 and the light-emitting layer 164. Accordingly, the light-emitting layer 164 may be cut off due to the undercut structure to thereby expose a part of the second auxiliary electrode 136, and the second electrode 166 may not be cut off due to the undercut structure and may be in contact with the exposed second auxiliary electrode 136.

Specifically, the planarization layer 140 and the bank layer 150 disposed between the second auxiliary electrode 136 and the light-emitting layer 164 may have a hole exposing the second auxiliary electrode 136. A top width of the hole of the planarization layer 140 may be greater than a bottom width of the hole of the bank layer 150, thereby forming the undercut structure in which the bottom surface of the bank layer 150 is exposed.

As described above, the light-emitting layer 164 may be formed through a thermal evaporation method with relatively low step coverage characteristics. At the side surface of the bank layer 150 corresponding to the undercut structure, the light-emitting layer 164 may have a thickness that decreases as it approaches or gets closer to the substrate 100 and then be cut off by the undercut structure. Therefore, the portion of the light-emitting layer 164 on the side surface of the bank layer 150 may be separated from the portion of the light-emitting layer 164 on the second auxiliary electrode 136, and the top surface of the second auxiliary electrode 136 corresponding to the undercut structure may be exposed.

On the other hand, the second electrode 166 may be formed through a sputtering method with relatively high step coverage characteristics. The second electrode 166 may not be cut off by the undercut structure. Accordingly, the second electrode 166 may be formed along the side and bottom surfaces of the bank layer 150 and the side surface of the planarization layer 140. The second electrode 166 may be in contact with the top surface of the second auxiliary electrode 136 exposed to correspond to the undercut structure and may be electrically connected to the first auxiliary electrode 126 and the power line 104 through the second auxiliary electrode 136.

Next, a capping layer 168 may be formed on the second electrode 166. The capping layer 168 may not be cut off to correspond to the undercut structure. The capping layer 168 may be in contact with the side surface of the spacer 155 and may be spaced apart from the top surface of the spacer 155 without contacting the top surface of the spacer 155. The capping layer 168 may not be provided in the second sub-pixel SP2.

The capping layer 168 may be formed of an insulating material having a relatively high refractive index. The wavelength of light traveling along the capping layer 168 may be amplified by surface plasma resonance. Thus, the intensity of the peak can be increased, thereby improving the light efficiency.

An encapsulation layer 170 may be provided on the capping layer 168. The encapsulation layer 170 may protect the first light-emitting element 160 from external moisture or oxygen. The encapsulation layer 170 may be provided between the first sub-pixel SP1 and the second sub-pixel SP2 and may not be provided in the second sub-pixel SP2.

The encapsulation layer 170 may include at least one inorganic insulation layer and at least one organic insulation layer. For example, the encapsulation layer 170 may have a triple-layered structure including first, second, and third encapsulation layers 172, 174, and 176.

Here, the first encapsulation layer 172 and the third encapsulation layer 176 may be formed of an inorganic insulating material, and the second encapsulation layer 174 may be formed of an organic insulating material. The second encapsulation layer 174 may be disposed between the first encapsulation layer 172 and the third encapsulation layer 176. The second encapsulation layer 174 may serve as a particle cover layer protecting the first light-emitting element 160 from particles, and a thickness of the second encapsulation layer 174 may be greater than thicknesses of the first and third encapsulation layers 172 and 176. In addition, the first and third encapsulation layers 172 and 176 may be in contact with each other, and the second encapsulation layer 174 may be enclosed by the first and third encapsulation layers 172 and 176.

When the second encapsulation layer 174 is formed, to prevent a material of the second encapsulation layer 174 from overflowing into the second sub-pixel SP2, at least one dam structure DM may be provided between the first sub-pixel SP1 and the second sub-pixel SP2.

The dam structure DM may include a plurality of dam portions 140a, 150a, and 155a sequentially stacked. For example, the dam structure DM may include a first dam portion 140a, a second dam portion 150a, and a third dam portion 155a. The first dam portion 140a may be a part of the planarization layer 140, the second dam portion 150a may be a part of the bank layer 150, and the third dam portion 155a may be the spacer 155.

The dam structure DM may be spaced apart from the first sub-pixel SP1 and the second sub-pixel SP2, and the top surface of the interlayer insulation layer 130 may be exposed between the first sub-pixel SP1 and the second sub-pixel SP2. In this case, the first distance d1 between the dam structure DM and the first sub-pixel SP1 may be greater than the second distance d2 between the dam structure DM and the second sub-pixel SP2 or between the dam structure DM and the third sub-pixel SP3.

The second encapsulation layer 174 may be provided inside the dam structure DM and may be substantially surrounded by the dam structure DM. On the other hand, the first encapsulation layer 172 and the third encapsulation layer 176 may be provided inside the dam structure DM and also provided outside the dam structure DM, thereby covering the dam structure DM.

Accordingly, the first encapsulation layer 172 and the third encapsulation layer 176 may be provided on the top and side surfaces of the dam structure DM and also provided on the top surface of the interlayer insulation layer 130 exposed between the dam structure DM and the second sub-pixel SP2. Here, the first encapsulation layer 172 may be in contact with the side surfaces of the first, second, and third dam portions 140a, 150a, and 155a and the top surface of the interlayer insulation layer 130.

In addition, the first encapsulation layer 172 and the third encapsulation layer 176 may be in contact with the side surface of the planarization layer 140 provided in the second sub-pixel SP2.

Meanwhile, an adhesive layer 180 may be provided on the first electrode 162 and the planarization layer 140 in the second sub-pixel SP2. The adhesive layer 180 may be an anisotropic conductive film (ACF) including an insulating base member and a plurality of conductive balls dispersed in the insulating base member. When heat or pressure is applied to the adhesive layer 180, in an area where the heat or pressure is applied, the conductive balls may be electrically connected, so that the adhesive layer 180 may have a conductive property, and in an area where the heat or pressure is not applied, the adhesive layer 180 may have an insulating property.

The second light-emitting element 190 may be provided on the adhesive layer 180 in the second sub-pixel SP2. The second light-emitting element 190 may include a first element electrode 192 overlapping the first electrode 162. The first element electrode 192 may be electrically connected to the first electrode 162 through the adhesive layer 180.

In addition, a third electrode spaced apart from the first electrode 162 may be further provided between the planarization layer 140 and the adhesive layer 180 in the second sub-pixel SP2, and the second light-emitting element 190 may further include a second element electrode electrically connected to the third electrode.

Here, the first element electrode 192 may be a p-electrode, and the second element electrode may be an n-electrode. However, embodiments of the present disclosure are not limited thereto. Alternatively, in other embodiments, the first element electrode 192 may be an n-electrode, and the second element electrode may be a p-electrode.

The second light-emitting element 190 may be provided in the form of a micro light-emitting diode chip (micro-LED chip or μLED chip) including the n-electrode, an n-type layer, an active layer, a p-type layer, and the p-electrode. The light-emitting element 190 may have a flip-chip structure in which the n-electrode and the p-electrode are provided on the same side (for example, a side facing the substrate 100) and light is emitted through a side opposite to the side provided with the n-electrode and the p-electrode (for example, a side opposite to the side facing the substrate 100).

However, embodiments of the present disclosure are not limited thereto. In other embodiments, the light-emitting element 190 may have a lateral structure in which the n-electrode and the p-electrode are provided on the same side and light is emitted through the same side provided with the n-electrode and the p-electrode or may have a vertical structure in which the n-electrode and the p-electrode are provided on opposite sides, respectively.

The second light-emitting element 190 may be an inorganic light-emitting diode, and the second light-emitting element 190 may emit one of green light and blue light. In addition, the second light-emitting element 190 may have a size of several tens of micrometers or less.

As such, in the light-emitting diode display device according to the embodiment of the present disclosure, the organic light-emitting diode having relatively high quantum efficiency of red light and the inorganic light-emitting diode having relatively high quantum efficiency of green or blue light may be included together in one pixel P, thereby improving light efficiency. Accordingly, the brightness can be increased, and the lifetime can be increased.

In this case, since the first light-emitting element 160, which is an organic light-emitting diode, may be vulnerable to moisture, etc., the first light-emitting element 160 may be covered and protected by the encapsulation layer 170. On other hand, in one embodiment, the second light-emitting element 190, which is an inorganic light-emitting diode, is spaced apart from the encapsulation layer 170 considering the light efficiency. To form the encapsulation layer 170, the dam structure DM is required between the first light-emitting element 160 and the second light-emitting element 190.

Accordingly, a separation distance between the first light-emitting element 160 and the second light-emitting element 190 may be a predetermined value or more. For example, the separation distance between the first light-emitting element 160 and the second light-emitting element 190 may be 100 μm or more. The resolution of the light-emitting diode display device may be limited by the distance.

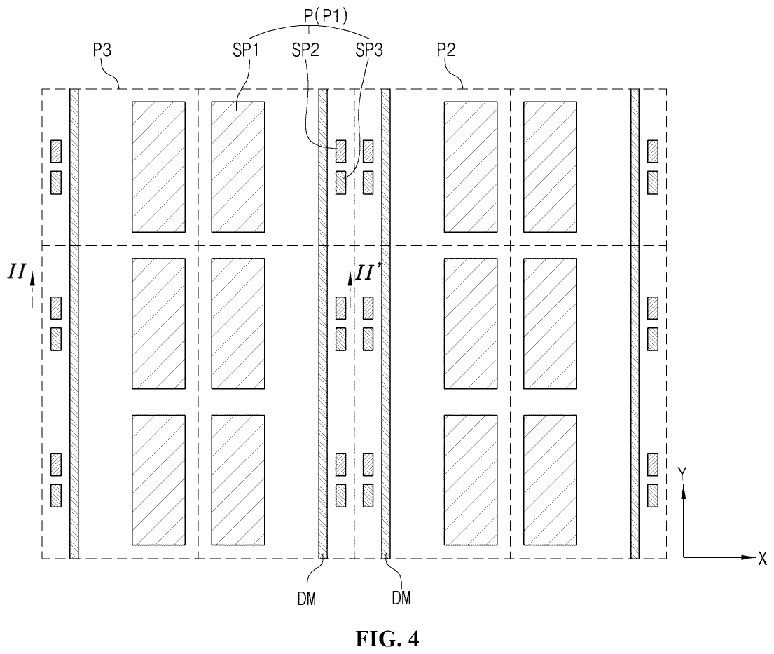

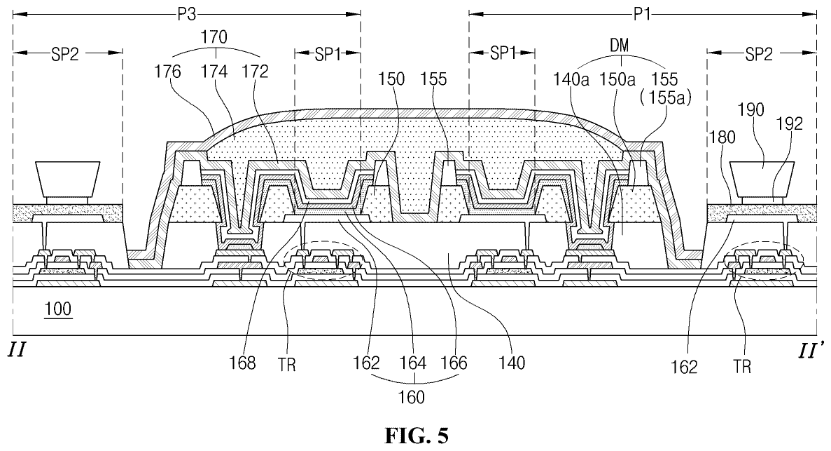

In the light-emitting diode display device according to the embodiment of the present disclosure, by arranging adjacent pixels symmetrically, the resolution can be increased. Such a light-emitting diode display device according to a first embodiment of the present disclosure will be described with reference to FIG. 4 and FIG. 5.

FIG. 4 is a schematic plan view of a light-emitting diode display device according to a first embodiment of the present disclosure, and FIG. 5 is a schematic cross-sectional view of a light-emitting diode display device according to the first embodiment of the present disclosure and shows a cross-section corresponding to line II-II′ of FIG. 4.

As shown in FIG. 4 and FIG. 5, in the light-emitting diode display device according to the first embodiment of the present disclosure, a plurality of pixels P may be arranged in the first direction X and the second direction Y Each pixel P may include the first sub-pixel SP1, the second sub-pixel SP2, and the third sub-pixel SP3. Two adjacent pixels P in the first direction X may have a symmetrical structure to each other.

Specifically, a first pixel P1 may be arranged adjacent to a second pixel P2 and a third pixel P3 in the first direction X. The first pixel P1 may be disposed between the second pixel P2 and the third pixel P3. In each of the first, second, and third pixels P1, P2, and P3, the first sub-pixels SP1 may be spaced apart from the second and third sub-pixels SP2 and SP3 in the first direction X, and the second sub-pixel SP2 and the third sub-pixel SP3 may be spaced apart from each other in the second direction Y.

In this case, the second sub-pixels SP2 of the first and second pixels P1 and P2 adjacent to each other in the first direction X may be placed adjacent to each other in the first direction X and may be disposed between the first sub-pixels SP1 of the first and second pixels P1 and P2. The third sub-pixels SP3 of the first and second pixels P1 and P2 may be placed adjacent to each other in the first direction X and may be disposed between the first sub-pixels SP1 of the first and second pixels P1 and P2. Accordingly, the first, second, and third sub-pixels SP1, SP2, and SP3 of the first pixel P1 may be arranged symmetrically with the first, second, and third sub-pixels SP1, SP2, and SP3 of the second pixel P2.

In addition, the first sub-pixels SP1 of the first and third pixels P1 and P3 adjacent to each other in the first direction X may be placed adjacent to each other in the first direction X and may be disposed between the second sub-pixels SP2 of the first and third pixels P1 and P3 and between the third sub-pixels SP3 of the first and third pixels P1 and P3. Accordingly, the first, second, and third sub-pixels SP1, SP2, and SP3 of the first pixel P1 may be arranged symmetrically with the first, second, and third sub-pixels SP1, SP2, and SP3 of the third pixel P3.

Each of the first, second, and third sub-pixels SP1, SP2, and SP3 may have a rectangular shape. Here, the first sub-pixel SP1 may have a rectangular shape in which a length of the second direction Y is longer than a length of the first direction X.

Meanwhile, the dam structure DM may be provided between the first sub-pixel SP1 and the second and third sub-pixels SP2 and SP3 of each of the first, second, and third pixels P1, P2, and P3. Accordingly, the first sub-pixels SP1 of the first and third pixels P1 and P3 adjacent to each other in the first direction X may be disposed between two dam structures DM adjacent to each other in the first direction X, that is, between the dam structure DM provided in the first pixel P1 and the dam structure DM provided in the third pixel P3. The second sub-pixel SP2 and third sub-pixel SP3 of the first and second pixels P1 and P2 adjacent to each other in the first direction X may be disposed between two dam structures DM adjacent to each other in the first direction X, that is, between the dam structure DM provided in the first pixel P1 and the dam structure DM provided in the second pixel P2.

The dam structures DM may extend in the second direction Y, and the dam structures DM provided in the pixels P adjacent in the second direction Y may be connected to each other.

The encapsulation layer 170 may be provided between the dam structure DM provided in the first pixel P1 and the dam structure DM provided in the third pixel P3. The encapsulation layer 170 may overlap the first sub-pixels SP1 of the first and third pixels P1 and P3 and protect first light-emitting elements 160 provided in the first sub-pixels SP1. The first light-emitting elements 160 may be an organic light-emitting diode.

The encapsulation layer 170 may be in contact with the top surface of the planarization layer 140 between the first sub-pixels SP1 of the first and third pixels P1 and P3. In this case, the spacer 155 may be provided on the bank layer 150 between the first sub-pixels SP1 of the first and third pixels P1 and P3. Accordingly, the encapsulation layer 170 may be in contact with the top surface of the planarization layer 140 between adjacent spacers 155. Specifically, the first encapsulation layer 172 of the encapsulation layer 170 may be in contact with the top surface of the planarization layer 140 between the adjacent spacers 155. In this case, each of the light-emitting layer 164, the second electrode 166, and the capping layer 168 may be separated for the first sub-pixels SP1 of the first and third pixels P1 and P3.

On the other hand, the encapsulation layer 170 may not be provided between the dam structure DM provided in the first pixel P1 and the dam structure DM provided in the second pixel P2. Accordingly, the encapsulation layer 170 may not overlap the second and third sub-pixels SP2 and SP3 and may be spaced apart from the second light-emitting element 190 and the third light-emitting element provided in each of the second and third sub-pixels SP2 and SP3. The second light-emitting element 190 and the third light-emitting element may be an inorganic light-emitting diode.

Here, the distance between the dam structures DM provided in the first and third pixels P1 and P3 may be greater than the distance between the dam structures DM provided in the first and second pixels P1 and P2. In addition, the distance between the dam structures DM provided in the first and second pixels P1 and P2 may be greater than the distance between the first sub-pixels SP1 of the first and third pixels P1 and P3. Accordingly, the distance between the dam structures DM provided in the first and third pixels P1 and P3 may be greater than the distance between the first sub-pixels SP1 of the first and third pixels P1 and P3.

As such, in the light-emitting diode display device according to the first embodiment of the present disclosure including the organic light-emitting diode and the inorganic light-emitting diode, the adjacent pixels P may be placed symmetrically, thereby increasing the resolution. For example, the light-emitting diode display device according to the first embodiment of the present disclosure may have the high resolution of 100 PPI or more.

On the other hand, when the adjacent pixels P are not placed symmetrically, the dam structure DM may be required not only between the first sub-pixel SP1 and the second and third sub-pixels SP2 and SP3 of one pixel P but also between the adjacent pixels P, specifically, between the first sub-pixel SP1 of one pixel P and second and third sub-pixels SP2 and SP3 of another pixel P adjacent thereto.

Accordingly, the separation distance from the second light-emitting element 190 and the third light-emitting element may be required at both sides of the first light-emitting element 160 provided in the first sub-pixel SP1 of each pixel P, thereby decreasing the resolution that can be implemented in the display device having the same size. For example, when the adjacent pixels P are not placed symmetrically, the maximum achievable resolution may be less than 100 PPI.

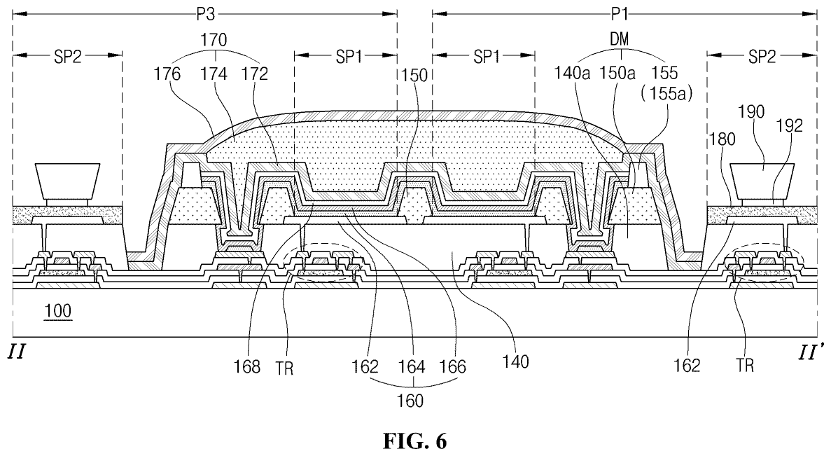

Meanwhile, the spacer 155 may be omitted between the first sub-pixels SP1 of the first and third pixels P1 and P3. Such a light-emitting diode display device of another example according to the first embodiment of the present disclosure will be described with reference to FIG. 6.

FIG. 6 is a schematic cross-sectional view of a light-emitting diode display device of another example according to the first embodiment of the present disclosure and shows a cross-section corresponding to line II-II′ of FIG. 4.

In FIG. 6, the bank layer 150 between the first sub-pixels SP1 of the first and third pixels P1 and P3 may cover the edges of the first electrodes 162 of the adjacent first sub-pixels SP1, and the spacer 155 may not be provided on the bank layer 150.

Then, the light-emitting layer 164, the second electrode 166, and the capping layer 168 may be sequentially formed on the bank layer 150 between the adjacent first sub-pixels SP1, and the encapsulation layer 170 may be formed on the capping layer 168. The encapsulation layer 170 may not be in contact with the top surface of the planarization layer 140.

Here, the light-emitting layer 164, the second electrode 166, and the capping layer 168 provided in the first sub-pixel SP1 of the first pixel P1 may be connected to the light-emitting layer 164, the second electrode 166, and the capping layer 168 provided in the first sub-pixel SP1 of the third pixel P3, respectively.

In the light-emitting diode display device of another example according to the first embodiment of the present disclosure, the distance between the first sub-pixels SP1 of the first and third pixels P1 and P3 can decrease compared to the configuration of FIG. 5. Accordingly, the area of the first sub-pixels SP1 may increase, thereby improving the brightness.

In addition, since the second electrode 166 of the first sub-pixel SP1 of the first pixel P1 is connected to the second electrode 166 of the first sub-pixel SP1 of the third pixel P3, the resistance of the second electrodes 166 may be lowered compared to the configuration of FIG. 5.

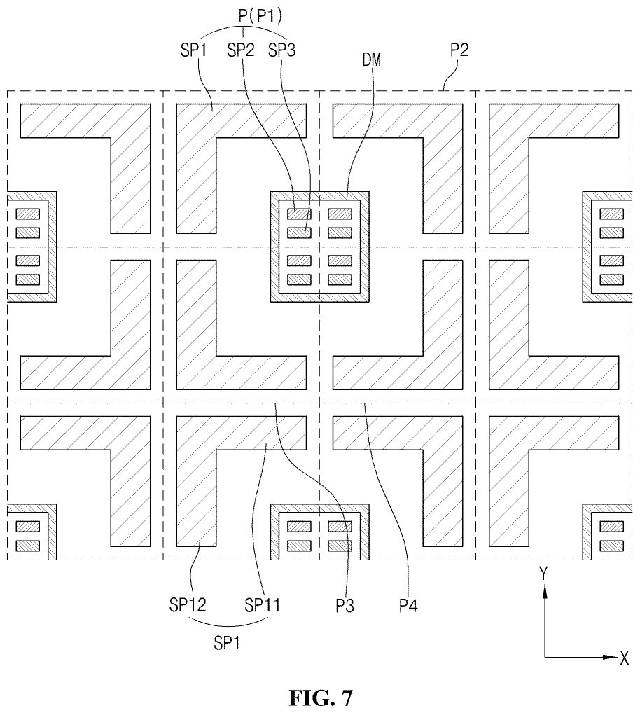

The first sub-pixel SP1 may have various shapes, and the pixel arrangement and the dam structure DM may vary depending on the shapes of the first sub-pixel SP1. Such a light-emitting diode display device according to a second embodiment of the present disclosure will be described with reference to FIG. 7.

FIG. 7 is a schematic plan view of a light-emitting diode display device according to a second embodiment of the present disclosure. The light-emitting diode display device according to a second embodiment of the present disclosure has substantially the same configuration as that of the first embodiment, except for the first sub-pixel, the pixel arrangement, and the dam structure. The same parts as those of the first embodiment are designated by the same or similar reference signs, and explanation for the same parts may be shortened or omitted.

As shown in FIG. 7, in the light-emitting diode display device according to the second embodiment of the present disclosure, the plurality of pixels P may be arranged in the first direction X and the second direction Y Each pixel P may include the first sub-pixel SP1, the second sub-pixel SP2, and the third sub-pixel SP3. Two adjacent pixels P in the first direction X may have a symmetrical structure to each other, and two adjacent pixels P in the second direction Y may have a symmetrical structure to each other.

Specifically, a first pixel P1 and a second pixel P2 may be arranged adjacent to each other in the first direction X, and a third pixel P3 and a fourth pixel P4 may be arranged adjacent to each other in the first direction X. The first pixel P1 and the third pixel P3 may be arranged adjacent to each other in the second direction Y, and the second pixel P2 and the fourth pixel P4 may be arranged adjacent to each other in the second direction Y.

In this case, the second and third sub-pixels SP2 and SP3 of the first and second pixels P1 and P2 adjacent to each other in the first direction X may be disposed between the first sub-pixels SP1 of the first and second pixels P1 and P2. The second and third sub-pixels SP2 and SP3 of the third and fourth pixels P3 and P4 adjacent to each other in the first direction X may be disposed between the first sub-pixels SP1 of the third and fourth pixels P3 and P4.

The first, second, and third sub-pixels SP1, SP2, and SP3 of the first pixel P1 may be arranged symmetrically with the first, second, and third sub-pixels SP1, SP2, and SP3 of the second pixel P2, and the first, second, and third sub-pixels SP1, SP2, and SP3 of the third pixel P3 may be arranged symmetrically with the first, second, and third sub-pixels SP1, SP2, and SP3 of the fourth pixel P4.

Meanwhile, the second and third sub-pixels SP2 and SP3 of the first and third pixels P1 and P3 adjacent to each other in the second direction Y may be disposed between the first sub-pixels SP1 of the first and third pixels P1 and P3, and the second and third sub-pixels SP2 and SP3 of the second and fourth pixels P2 and P4 adjacent to each other in the second direction Y may be disposed between the first sub-pixels SP1 of the second and fourth pixels P2 and P4.

The first sub-pixel SP1 of the first pixel P1 may be arranged symmetrically with the first sub-pixel SP1 of the third pixel P3, and the first sub-pixel SP1 of the second pixel P2 may be arranged symmetrically with the first sub-pixel SP1 of the fourth pixel P4. In addition, the second and third sub-pixels SP2 and SP3 of the first pixel P1 may be arranged symmetrically with the second and third sub-pixels SP2 and SP3 of the third pixel P3, and the second and third sub-pixels SP2 and SP3 of the second pixel P2 may be arranged symmetrically with the second and third sub-pixels SP2 and SP3 of the fourth pixel P4.

Accordingly, the first sub-pixels SP1 of the first, second, third, and fourth pixels P1, P2, P3, and P4 may surround the second and third sub-pixels SP2 and SP3 of the first, second, third, and fourth pixels P1, P2, P3, and P4.

Here, the first sub-pixel SP1 of each of the first, second, third, and fourth pixels P1, P2, P3, and P4 may include a first portion SP11 parallel to the first direction X and a second portion SP12 parallel to the second direction Y and may have a substantially L-like shape.

In each of the first, second, third, and fourth pixels P1, P2, P3, and P4, the dam structure DM may be provided between the first sub-pixel SP1 and the second and third sub-pixels SP2 and SP3. The dam structures DM provided respectively in the first, second, third, and fourth pixels P1, P2, P3, and P4 may be connected to each other and may surround the second and third sub-pixels SP2 and SP3 of the first, second, third, and fourth pixels P1, P2, P3, and P4.

In addition, the first sub-pixels SP1 of the first, second, third, and fourth pixels P1, P2, P3, and P4 may surround substantially the dam structures DM provided respectively in the first, second, third, and fourth pixels P1, P2, P3, and P4.

Here, the dam structures DM provided respectively in the first, second, third, and fourth pixels P1, P2, P3, and P4 may be spaced apart from dam structures DM provided respectively in other first, second, third, and fourth pixels P1, P2, P3, and P4 adjacent thereto.

As such, in the light-emitting diode display device according to the second embodiment of the present disclosure, the first sub-pixel SP1 may have a substantially L-like shape, and the dam structures DM may surround the second and third sub-pixels SP2 and SP3 of the first, second, third, and fourth pixels P1, P2, P3, and P4 adjacent in the first direction X and the second direction Y, so that the area of the first sub-pixel SP1, that is, the area of the first light-emitting element 160 can be increased compared with the first embodiment while implementing the high resolution. Accordingly, the brightness of the display device may be further improved, and the lifetime may also be further increased.

The light-emitting diode display device according to the second embodiment of the present disclosure may have substantially the same cross-sectional configuration as that of FIG. 5 or FIG. 6.

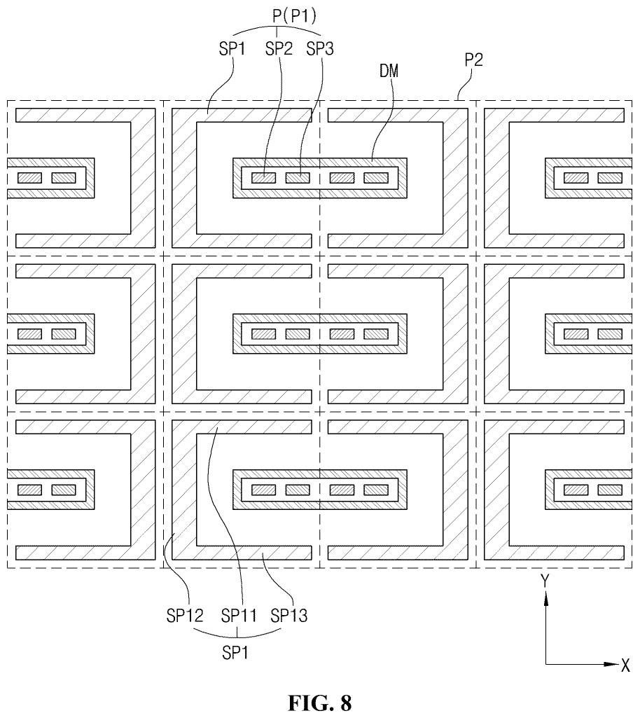

FIG. 8 is a schematic plan view of a light-emitting diode display device according to a third embodiment of the present disclosure. The light-emitting diode display device according to a third embodiment of the present disclosure has substantially the same configuration as those of the first and second embodiments, except for the first sub-pixel, the pixel arrangement, and the dam structure. The same parts as those of the first and second embodiments are designated by the same or similar reference signs, and explanation for the same parts may be shortened or omitted.

As shown in FIG. 8, in the light-emitting diode display device according to the third embodiment of the present disclosure, the plurality of pixels P may be arranged in the first direction X and the second direction Y Each pixel P may include the first sub-pixel SP1, the second sub-pixel SP2, and the third sub-pixel SP3. Two adjacent pixels P in the first direction X may have a symmetrical structure to each other.

Specifically, a first pixel P1 and a second pixel P2 may be arranged adjacent to each other in the first direction X. The second and third sub-pixels SP2 and SP3 of the first and second pixels P1 and P2 may be disposed between the first sub-pixels SP1 of the first and second pixels P1 and P2. In this case, the second and third sub-pixels SP2 and SP3 may be spaced apart from each other in the first direction X.

The first sub-pixels SP1 of the first and second pixels P1 and P2 may be arranged symmetrically with each other. In addition, the second and third sub-pixels SP2 and SP3 of the first pixel P1 may also be arranged symmetrically with the second and third sub-pixels SP2 and SP3 of the second pixel P2.

Here, the first sub-pixel SP1 of each of the first and second pixels P1 and P2 may include first, second, and third portions SP11, SP12, and SP13. The first and third portions SP11 and SP13 may extend to be parallel to the first direction X, and the second portion SP12 may extend to be parallel to the second direction Y The second portion SP12 may be disposed between the first portion SP11 and the third portion SP13. The first sub-pixels SP1 of the first and second pixels P1 and P2 may have a substantially angled U-like shape.

The first sub-pixels SP1 of the first and second pixels P1 and P2 may surround the second and third sub-pixels SP2 and SP3 of the first and second pixels P1 and P2.

The dam structure DM may be provided between the first sub-pixel SP1 and the second and third sub-pixels SP2 and SP3 of each of the first and second pixels P1 and P2. The dam structures DM provided respectively in the first and second pixels P1 and P2 may be connected to each other and may surround the second and third sub-pixels SP2 and SP3 of the first and second pixels P1 and P2.

Here, the dam structures DM provided respectively in the first and second pixels P1 and P2 may be spaced apart from dam structures DM provided respectively in other first and second pixels P1 and P2.

As such, in the light-emitting diode display device according to the third embodiment of the present disclosure, the first sub-pixel SP1 may have a substantially angled U-like shape, and the dam structures DM may surround the second and third sub-pixels SP2 and SP3 of the first and second pixels P1 and P2 adjacent in the first direction X, so that the visibility can be increased compared with the second embodiment in which four second and third sub-pixels SP2 and SP3 are arranged adjacent to each other.

The light-emitting diode display device according to the third embodiment of the present disclosure may have substantially the same cross-sectional configuration as that of FIG. 5 or FIG. 6.

In the light-emitting diode display device of the present disclosure, by applying the organic light-emitting diode and the inorganic light-emitting diode having the relatively high quantum efficiency together in one pixel, the light efficiency may be improved, so that the brightness of the display device can be increased, and the lifetime can be increased.

In addition, by arranging the adjacent pixels symmetrically, the resolution can be increased.

Moreover, the area of the sub-pixel may be increased, so that the brightness of the display device can be further improved, and the lifetime can be further increased.

Accordingly, the power consumption can be reduced due to the increase in efficiency of the light-emitting diode and the improved lifetime of the light-emitting diode, thereby achieving the low power consumption.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A light-emitting diode display device, comprising:
a substrate;
a plurality of pixels arranged in a first direction and a second direction on the substrate, each of the plurality of pixels including a first sub-pixel and a second sub-pixel;
a first light-emitting element in the first sub-pixel;
a second light-emitting element in the second sub-pixel; and
a dam structure between the first sub-pixel and the second sub-pixel of each of the plurality of pixels,
wherein first sub-pixels of two pixels from the plurality of pixels that adjacent to each other in the first direction are between second sub-pixels of the two pixels and between dam structures provided in the two pixels.

2. The light-emitting diode display device of claim 1, wherein a distance between the dam structures provided in the two pixels is greater than a distance between the first sub-pixels of the two pixels.

3. The light-emitting diode display device of claim 1, wherein in each of the plurality of pixels, a distance between the dam structure and the first sub-pixel is greater than a distance between the dam structure and the second sub-pixel.

4. The light-emitting diode display device of claim 1, wherein the first sub-pixel includes a first portion extending in the first direction and a second portion extending in the second direction.

5. The light-emitting diode display device of claim 4, wherein the first sub-pixels of two pixels adjacent to each other in the first direction or the second direction are arranged symmetrically with each other.

6. The light-emitting diode display device of claim 4, wherein the dam structure surrounds second sub-pixels of four pixels from the plurality of pixels that are adjacent to each other in the first direction and the second direction.

7. The light-emitting diode display device of claim 4, wherein the first sub-pixel further includes a third portion extending in the first direction, and the second portion is between the first portion and the third portion.

8. The light-emitting diode display device of claim 7, wherein the first sub-pixels of two pixels from the plurality of pixels that are adjacent to each other in the first direction or the second direction are arranged symmetrically with each other.

9. The light-emitting diode display device of claim 7, wherein the dam structure surrounds the second sub-pixels of two pixels from the plurality of pixels that are adjacent to each other in the first direction.

10. The light-emitting diode display device of claim 1, wherein the first light-emitting element is an organic light-emitting diode, and the second light-emitting element is an inorganic light-emitting diode.

11. The light-emitting diode display device of claim 10, further comprising:
an encapsulation layer on the first light-emitting element, the encapsulation layer spaced apart from the second light-emitting element.
